(19) United States
(12) Patent Application Publication
(10) Pub. No.: US 2026/0239579 A1
(43) Pub. Date: Aug. 13, 2026

(54) NON-EVAPORATIVE DATA CENTER HEAT REJECTION WITH THERMAL ENERGY STORAGE

(71) Applicant: Gary HILBERG, Monroe, OR (US)

(72) Inventor: Gary HILBERG, Monroe, OR (US)

(21) Appl. No.: 19/240,920

(22) Filed: Jun. 17, 2025

Related U.S. Application Data
(60) Provisional application No. 63/757,599, filed on Feb. 12, 2025.

(51) Int. Cl. H05K 7/20

(52) U.S. Cl. CPC H05K 7/2079

(57) ABSTRACT

A non-evaporative data center heat rejection system includes a data center configured to receive cooling from a chilled water supply which is configured to return water to a chilled water return, a plurality of heat exchangers configured to receive water from the chilled water return, a plurality of mechanical chillers configured to receive water from the plurality of heat exchangers, a first plurality of pumps to pump chilled water from the plurality of mechanical chillers into the chilled water supply, a plurality of air coolers configured to receive chilled water from the mechanical chillers, a second plurality of pumps to output water into at least one of the heat exchangers, a thermal energy storage tank configured to variably output into and receive water from the chilled water return and the chilled water supply, and a control system to control components of the data center heat rejection system.

### BACKGROUND

The recent growth in AI and high-powered compute has caused the dramatic increase in data center growth, particularly in the United States, where 37,000 MW of new electrical generation capacity is expected to be needed between 2024 and 2030.

Data centers are rapidly growing in size and density, leading to increased cooling demands. Traditional cooling methods, such as direct air heat rejection, are not compatible with the new generation of high-density server racks that require liquid cooling. Existing liquid cooling solutions often rely on evaporative cooling, which consumes large amounts of water. This presents a challenge for data centers located in water-stressed regions.

### SUMMARY

A non-evaporative data center heat rejection system includes a data center configured to receive cooling from a chilled water supply which is configured to return water to a chilled water return, a plurality of heat exchangers configured to receive water from the chilled water return, a plurality of mechanical chillers configured to receive water from the plurality of heat exchangers, a first plurality of pumps to pump chilled water from the plurality of mechanical chillers into the chilled water supply, a plurality of air coolers configured to receive condenser water from the mechanical chillers and/or the heat exchangers, a second plurality of pumps to output water into at least one of the heat exchangers, a thermal energy storage tank configured to variably output into and receive water from the chilled water return and the chilled water supply, and a control system to control components of the data center heat rejection system.

### BRIEF DESCRIPTION OF THE FIGURES

Advantages of embodiments of the present invention will be apparent from the following detailed description of the exemplary embodiments. The following detailed description should be considered in conjunction with the accompanying figures in which:

FIG. 1 shows an exemplary data center heat rejection system.

FIG. 2 shows an exemplary method for data center heat rejection.

FIG. 3 shows a chart comparing A/C heat rejection efficiency with ambient dry bulb temperature according to one exemplary embodiment.

### DETAILED DESCRIPTION

Aspects of the invention are disclosed in the following description and related drawings directed to specific embodiments of the invention. Alternate embodiments may be devised without departing from the spirit or the scope of the invention. Additionally, well-known elements of exemplary embodiments of the invention will not be described in detail or will be omitted so as not to obscure the relevant details of the invention. Further, to facilitate an understanding of the description discussion of several terms used herein follows.

As used herein, the word “exemplary” means “serving as an example, instance or illustration.” The embodiments described herein are not limiting, but rather are exemplary only. It should be understood that the described embodiments are not necessarily to be construed as preferred or advantageous over other embodiments. Moreover, the terms “embodiments of the invention”, “embodiments” or “invention” do not require that all embodiments of the invention include the discussed feature, advantage or mode of operation.

Further, many of the embodiments described herein are described in terms of sequences of actions to be performed by, for example, elements of a computing device. It should be recognized by those skilled in the art that the various sequence of actions described herein can be performed by specific circuits (e.g., application specific integrated circuits (ASICs)) and/or by program instructions executed by at least one processor. Additionally, the sequence of actions described herein can be embodied entirely within any form of computer-readable storage medium such that execution of the sequence of actions enables the processor to perform the functionality described herein. Thus, the various aspects of the present invention may be embodied in a number of different forms, all of which have been contemplated to be within the scope of the claimed subject matter. In addition, for each of the embodiments described herein, the corresponding form of any such embodiments may be described herein as, for example, a computer configured to perform the described action.

Many of the embodiments described herein are described in terms of sequences of actions to be performed by, for example, an Artificial Intelligence (AI) module or modules. It will be understood by those skilled in the art that the sequence of actions described herein can be embodied entirely within any form of AI or ML architecture such that execution of the sequence of actions enables the processor to perform the functionality described herein. Thus, the various aspects of the present invention may be embodied in a number of different forms, all of which have been contemplated to be within the scope of the claimed subject matter. For example, machine learning architectures include but are not limited to Artificial Neural Networks (ANNs), Multi-Layer-Perceptrons (MLPs), Support Vector Machines (SVMs), Recurrent Neural Networks (RNNs), Convolutional Neural Networks (CNNs), Large Language Models (LLMs), transformers, decision trees, random forests, nearest neighbor models, clustering algorithms, expert systems, mixture of experts models, ensemble models, diffusion models, reinforcement learning, and autoencoder models, to name a few. However, many other forms of AI and ML architectures that enable the processor to perform the same functionality have been considered.

It may generally be contemplated for any AI or machine learning architecture to be retrained according to the data processed herein, for example automatically or continuously retrained on a predetermined schedule or based on one or more triggers, such as based on one or more detected changes in the data.

It may be contemplated for execution of the sequence of actions contemplated to be undertaken by the AI or ML architecture to be based on data retrieved from any sensor contemplated herein, and for execution of the sequence of actions to include actuation of any of the one or more transducers contemplated herein.

In one or more exemplary embodiments a data center heat rejection system may be provided.

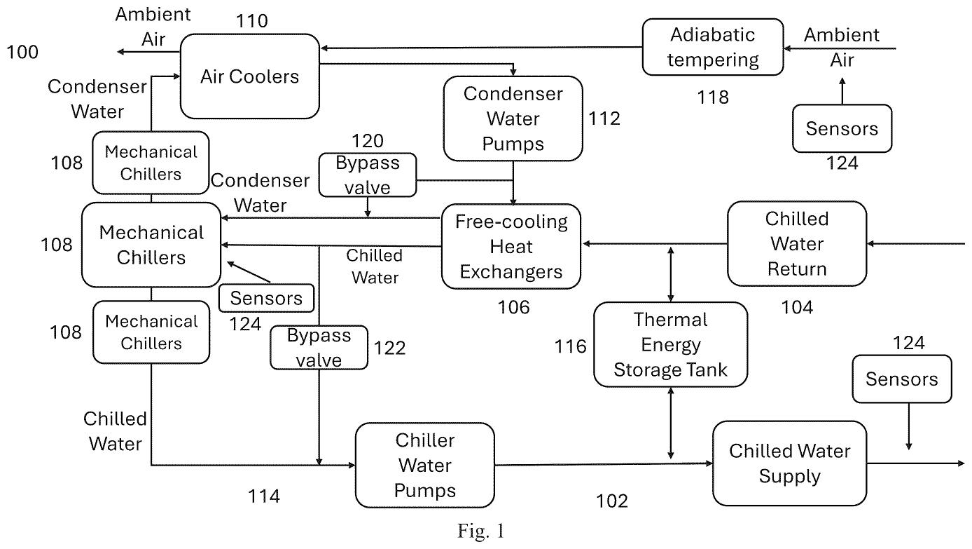

Referring to FIG. 1, an exemplary data center heat rejection system 100 may be shown and described. The data center heat rejection system 100 may include a data center 10. In some exemplary embodiments, the data center 10 may comprise a plurality of servers, computers, data storage devices, processors, and/or other heat producing units. In some exemplary embodiments, heat may be removed from air surrounding the data center 10 via pipes of chilled water. The chilled water may be provided by a chilled water supply 102 and may return to a chilled water return 104 after heat is absorbed into the water.

In some embodiments, the chilled water may remove heat from the data center 10 by means of, for example, air heat exchangers, liquid heat exchangers, cooling distribution units (CDU's), heat exchangers in immersion cooling systems and/or other heat exchangers. In some embodiments, the chilled water may remove heat from a variety of data center equipment including but not limited to chips, servers, UPS systems, and other heat producing machines.

The data center heat rejection system 100 may include a plurality of heat exchangers 106. In some embodiments, the heat exchangers 106 may include free cooling heat exchangers. Free cooling may be understood to mean utilizing low external ambient temperature to assist or replace electrically expensive cooling methods such as, for example, mechanical chilling. In one embodiment, the heat exchangers 106 may be plate and frame heat exchangers. The heat exchangers 106 may receive heated water from the chilled water return 104. In some embodiments, the heat exchangers 106 may output chilled and heated water into a plurality of mechanical chillers 108. In some exemplary embodiments, chilled water temperatures and flow may be adjusted in response to changing data cooling requirements.

In some embodiments, the mechanical chillers 108 may be centrifugal chillers. In some embodiments, the mechanical chillers 108 may be optimized for high condenser temperatures and/or large cooling capacities. In some embodiments, the mechanical chillers 108 may use refrigerants, such as, for example, HFCs, low GWP refrigerants, or other refrigerants known to those skilled in the art. The mechanical chillers 108 may output chilled water to the chilled water supply 102 via a plurality of chilled water pumps 114. In some exemplary embodiments, the chilled water pumps 114 may be vertical centrifugal pumps.

In some exemplary embodiments, a plurality of the mechanical chillers 108 may be operated in series, cooling the chilled water in steps. For example, a first mechanical chiller may lower the chilled water temperature from 100° F. to 85° F., and a subsequent mechanical chiller may further lower the chilled water temperature from 85° F. to 70° F. By operating the mechanical chillers 108 in series, chilling cycle efficiency may be dramatically improved.

In some embodiments, the mechanical chillers 108 may output heated condenser water to a plurality of air coolers 110. In some exemplary embodiments, the air coolers 110 may be industrial scale air coolers with large diameter fans for efficient heat rejection. For example, fans having a diameter of at least ten feet may be used in some embodiments. The air coolers 110 may output water to the heat exchangers 106 via condenser water pumps 112 capable of varying condenser water flow. In some embodiments, the condenser water flow may be varied based on ambient or system conditions and/or cooling load factors. This may improve capacity and efficiency, and reduce mechanical chiller run times.

In some embodiments, the data center heat rejection system 100 may include an adiabatic tempering system 118. The adiabatic tempering system 118 may be, for example, an adiabatic fogger. In some exemplary embodiments, the adiabatic tempering system 118 may be located in front of the air coolers 110, and may accept ambient air.

In some embodiments, the data center heat rejection system 100 may include a heat exchanger bypass valve 120. The heat exchanger bypass valve 120 may allow condenser water to bypass one or more of the heat exchangers in varying amounts. In some embodiments, the data center heat rejection system 100 may include a mechanical chiller bypass valve 122. The mechanical chiller bypass valve 122 may allow chilled water to bypass one or more of the mechanical chillers in varying amounts. In some exemplary embodiments, these valves may be connected to a control system, which may be operated by a processor.

In some embodiments, the data center heat rejection system 100 may include a condenser water loop and a chilled water loop. In some embodiments, the condenser water may include an antifreeze agent, such as propylene glycol. In some exemplary embodiments, the loops may be kept separate, and only interact by a shared thermodynamic connection to a refrigerant loop within the mechanical chillers 108 or heat exchangers 106. This may allow heat to be transferred from the chilled water to the condenser water. In some exemplary embodiments, the chilled water heat may evaporate the refrigerant, after which a compressor may use electricity to compress the gaseous refrigerant. The compressed refrigerant may then be condensed at a higher temperature, allowing heat to pass to the condenser water. An expansion valve may then provide a desired amount of refrigerant back to the evaporator. In some embodiments, the amount of refrigerant returned to the evaporator may depend on the readings of a pressure, temperature, or other sensor. In some embodiments, the air coolers 110 may reject heat from the condenser water to the outside air.

In some embodiments, the data center heat rejection system 100 may include a Thermal Energy Storage (“TES”) tank 116. The TES tank 116 may be a thermally stratified water tank. In some exemplary embodiments, the data center heat rejection system 100 may include a control system and a plurality of sensors 124. The sensors 124 may include, for example, temperature sensors, cameras, microphones, energy consumption sensors, humidity sensors, or other sensors. The control system may receive data readings from the sensors 124. In some exemplary embodiments, the data may comprise temperature data and/or power consumption data, and the control system may comprise a processor. Other data may also be collected and used by the processor, such as, for example, current and future weather conditions, price of electricity, and projected capacity of the TES tank vs. demand profile. The control system may optimize performance by managing and actuating various components of the data center heat rejection system 100.

In some exemplary embodiments, the control system may operate the components of the data center heat rejection system 100 based on readings from the sensors 124. For example, the control system may operate in a free cooling mode, in which the heat exchangers provide some or all of the cooling, and the mechanical chillers 108 operate at reduced capacity or are deactivated. In another embodiment, the control system may operate in a chiller mode, with the mechanical chillers 108 fully or partially activated. In some embodiments, the control system may operate in a TES charging mode, in which the TES tank is charged with cooling capacity by the mechanical chillers 108. In some embodiments, the control system may operate in a TES discharging mode, in which cooling capacity from the TES tank is discharged to supplement the mechanical chillers 108. In some embodiments it may be preferable to employ TES discharging mode when demand for cooling is high, the chiller system lacks capacity due to ambient conditions or maintenance, and/or when energy usage is high. In some embodiments, sensors 124 may include electricity or other measures of system computing load to enable the chiller system to respond more quickly to increasing or decreasing cooling demands from the data center 10. Sensors 124 may be integrated with monitoring systems that may rapidly predict upcoming load shifts, while conventional controls may respond to water temperature changes which have high latency due to the distances and volumes of water in the system.

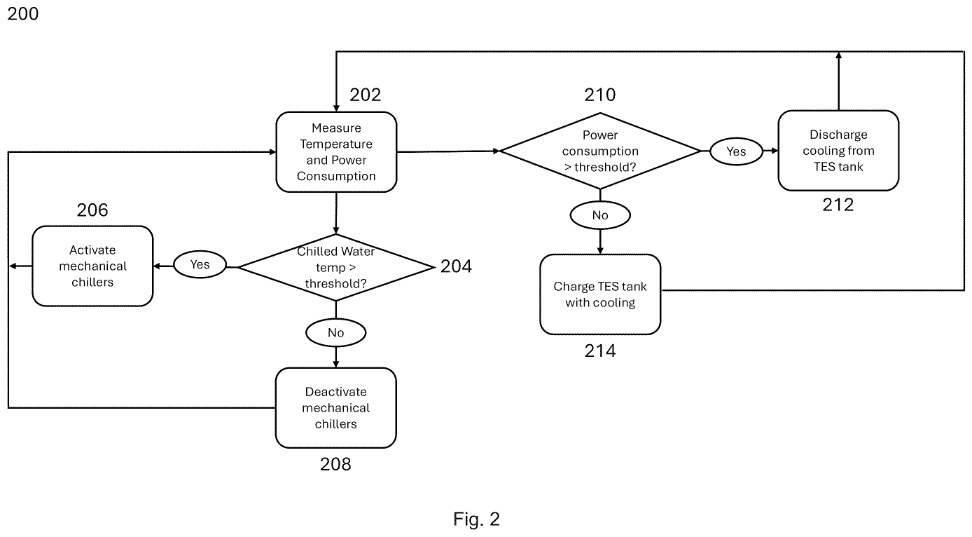

Referring to FIG. 2, an exemplary method for data center heat rejection 200 may be shown and described. The method 200 may include a first step 202, comprising receiving a control system a plurality of temperature and power consumption data from a plurality of sensors. A next step 204 may comprise checking the ambient and/or chilled water temperature readings against a predetermined temperature threshold. If the ambient or system temperature readings exceed the predetermined threshold, mechanical chillers may be activated 206 to lower the temperature. In some embodiments, the control system may simultaneously check if power consumption has exceeded a predetermined power consumption threshold 210. The power consumption threshold 210 may be linked to a commercial electrical demand-side management process. If power consumption has exceeded the predetermined power consumption threshold 210, cooling from the TES tank may then be discharged to supplement the mechanical chillers 212. If the power consumption is under the threshold, the TES tank may then be charged with cooling by the mechanical chillers for later use 214. It may be understood by those with skill in the art that this method may be conducted repeatedly and in real time.

In some exemplary embodiments, the method may involve a simulated digital twin of the system. The digital twin may use a computer system to emulate properties of and/or predict outcomes in the data center heat rejection system 100. This twin's expected performance may be updated with actual operating data to better model the actual performance of the system using AI/ML methods. For example, the digital twin may include a simulation of system efficiency, temperature, energy expenditure, and/or other calculated values to be used as predictions of how the system would perform under a given set of conditions. In some embodiments, the simulated values of the digital twin may be used in place of or alongside threshold values to activate or deactivate the mechanical chillers 212 or to charge or discharge the TES tank 116. In some embodiments, the digital twin may also simulate and/or receive input data regarding the price of electricity.

In some exemplary embodiments, the chilled water production temperature may be reduced and chilled water may be stored at a lower temperature, for example, below 70° F. This may increase the system capacity, allowing for more energy in the same volume. The return hot water may then be mixed with the colder chilled water to meet a required temperature. In an exemplary embodiment, this is done with free cooling, which allows the system to make use of low ambient temperature efficiently and with little to no power expenditure.

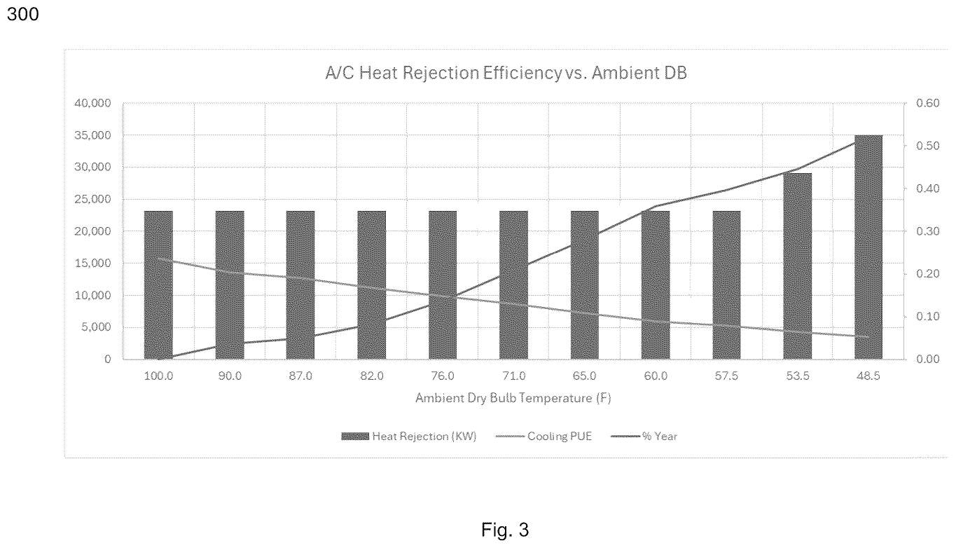

Referring to FIG. 3, a chart comparing A/C heat rejection efficiency with ambient dry bulb temperature may be shown. The chart may be understood to show the effects of dry bulb temperature on A/C heat rejection efficiency according to an exemplary embodiment of a heat rejection system. The exemplary embodiment may be, for example, the system described in FIG. 1. The chart of FIG. 3 demonstrates that overall heat rejection efficiency generally increases as ambient dry bulb temperature decreases, due to in part to the adaptive design of the heat rejection system. This may allow the system to save electricity while maximizing heat rejection, especially when the ambient temperature is low. This effect may serve to optimize the system by using expected future weather and/or chilled water demand data to reduce mechanical chiller load and discharge the TES tank during hot periods with the expectation that the near term future weather will allow a more efficient operating condition.

In one exemplary embodiment, the system may have a summer cooling capacity of 6,550 TR, a winter cooling capacity of 9,825 TR, and/or a cooling capacity of 23,014 KW. In another exemplary embodiment, the system may have dry bulb temperature design loads of 100° F. in the summer and 55° F. in the winter, and wet bulb temperature design loads of 74° F. in the summer and 58° F. in the winter.

In some embodiments, the system may reduce water consumption, increase energy efficiency, enhance system reliability, and reduce operating costs. In embodiments that adapt to changes in power and ambient temperature, the system may provide demand response to sudden increases in energy use and/or heat production.

The foregoing description and accompanying figures illustrate the principles, preferred embodiments and modes of operation of the invention. However, the invention should not be construed as being limited to the particular embodiments discussed above. Additional variations of the embodiments discussed above will be appreciated by those skilled in the art.

Therefore, the above-described embodiments should be regarded as illustrative rather than restrictive. Accordingly, it should be appreciated that variations to those embodiments can be made by those skilled in the art without departing from the scope of the invention as defined by the following claims.

1. A data center heat rejection system comprising:
a data center configured to receive cooling from a chilled water supply, the chilled water supply being configured to return water to a chilled water return;
a plurality of heat exchangers configured to receive chilled water from the chilled water return;
a plurality of mechanical chillers configured to receive water from the plurality of heat exchangers;
a first plurality of water pumps configured to pump chilled water from the plurality of mechanical chillers into the chilled water supply;
a plurality of air coolers, the air coolers configured to receive condenser water from the mechanical chillers;
a plurality of condenser water pumps configured to output water into at least one of the heat exchangers;
and
a control system comprising at least one processor, the control system being configured to actuate and control one or more valves of the data center heat rejection system.

2. The system of claim 1, wherein the one or more valves include at least one heat exchanger bypass valve that allows varying the condenser and/or chilled water to each of the mechanical chillers, air coolers, the condenser water pumps, and heat exchangers.

3. The system of claim 1, further comprising at least one mechanical chiller bypass valve.

4. The system of claim 1, wherein the air coolers include fans having a diameter of at least ten feet.

5. The system of claim 1, wherein the mechanical chillers are centrifugal chillers.

6. The system of claim 1, wherein the heat exchangers are free cooling plate and frame heat exchangers.

7. The system of claim 1, further comprising a thermal energy storage (TES) tank configured to variably output into and receive water from both the chilled water return and the chilled water supply.

8. The system of claim 1, further comprising a plurality of sensors configured to send data readings to the control system.

9. The system of claim 1, wherein the plurality of mechanical chillers are configured to be operated in series, each chiller further reducing the temperature of water received from a preceding chiller in the series.

10. The system of claim 8, wherein the data readings comprise changes in system computing load determined by the at least one processor based on the data readings sent to the control system.

11. The system of claim 7, further comprising a plurality of sensors configured to send data readings to the control system, wherein the control system is configured to compare ambient temperature readings from the plurality of sensors to a predetermined temperature threshold, and to operate in a TES charging mode when the ambient temperature readings do not exceed the predetermined temperature threshold and to operate in a TES discharging mode when the ambient temperature readings exceed the predetermined temperature threshold.

12. The system of claim 7, further comprising a plurality of sensors configured to send data readings to the control system, wherein the control system is configured to compare electrical power expenditure readings to a predetermined power consumption threshold, and to operate in a TES charging mode when the electrical power expenditure readings do not exceed the predetermined power consumption threshold and to operate in a TES discharging mode when the electrical power expenditure readings exceed the predetermined power consumption threshold.

13. A method of data center heat rejection comprising,
taking continuous ambient and system temperature and energy consumption readings from a plurality of sensors in real time;
comparing the ambient or system temperature readings to a predetermined temperature threshold value;
charging a thermal energy storage tank with cooling capacity with a plurality of mechanical chillers if the ambient or system temperature readings do not exceed the predetermined temperature threshold value;
discharging cooling capacity from the thermal energy storage tank if the ambient or system temperature readings exceed the predetermined temperature threshold value;
comparing the energy consumption readings to a predetermined energy consumption or energy price threshold value;
enabling at least one of the mechanical chillers if the energy consumption readings exceed the predetermined energy consumption or price threshold value; and
disabling the mechanical chillers if the energy consumption readings do not exceed the predetermined energy consumption threshold value.

14. The method of claim 13, wherein the predetermined temperature threshold value and the predetermined energy consumption threshold values are calculated based on a simulated digital twin of the system.

15. A computer implemented method of data center heat rejection comprising
a processor programmed to execute instructions from a non-transitory computer readable storage medium, the steps comprising
taking continuous ambient and system temperature and energy consumption readings from a plurality of sensors in real time;
comparing the ambient or system temperature readings to a predetermined temperature threshold value;
charging a thermal energy storage tank with cooling capacity with a plurality of mechanical chillers if the ambient or system temperature readings do not exceed the predetermined temperature threshold value;
discharging cooling capacity from the thermal energy storage tank if the ambient or system temperature readings exceed the predetermined temperature threshold value;
comparing the energy consumption readings to a predetermined energy consumption threshold value;
enabling at least one of the mechanical chillers if the energy consumption readings exceed the predetermined energy consumption threshold value; and
disabling the mechanical chillers if the energy consumption readings do not exceed the predetermined energy consumption threshold value.
